(19) United States
(12) Patent Application Publication
(10) Pub. No.: US 2025/0211186 A1
(43) Pub. Date: Jun. 26, 2025

(54) VOLUME ACOUSTIC DEVICE AND METHOD FOR PRODUCING A VOLUME ACOUSTIC DEVICE

(71) Applicant: Robert Bosch GmbH, Stuttgart (DE)

(72) Inventor: Christoph Schelling, Stuttgart (DE)

(21) Appl. No.: 18/845,454

(22) PCT Filed: Feb. 28, 2023
(86) PCT No.: PCT/EP2023/054961

§ 371 Date: Sep. 10, 2024

(30) Foreign Application Priority Data
Apr. 25, 2022 (DE) 10 2022 203 971.8

(51) Int. Cl. H03H 3/02; H03H 9/02; H03H 9/17

(52) U.S. Cl. CPC H03H 3/02; H03H 9/02015; H03H 9/175

(57) ABSTRACT

A volume acoustic device. The volume acoustic device includes a first electrode, a second electrode, and a piezoelectric element arranged between the first electrode and the second electrode. The piezoelectric element is configured such that a first electromagnetic signal supplied to the first electrode is converted into an acoustic signal in the piezoelectric element, and the acoustic signal is converted back into a second electromagnetic signal in the second electrode. The piezoelectric element includes at least two piezoelectric layers with a rectified polarity and at least one intermediate layer located between the at least two piezoelectric layers. Acoustic layer thicknesses of the piezoelectric layers and the intermediate layer each correspond to an odd-numbered multiple of half of the acoustic wavelength of an acoustic signal to be transmitted.

### FIELD

The present invention relates to a volume acoustic device and a method for producing a volume acoustic device.

### BACKGROUND INFORMATION

In high-frequency technology, bulk acoustic wave (BAW) components are used as resonators in filters and oscillators. The operating frequency of the components is primarily determined by the thickness of the piezoelectric layer and the sound velocity in the piezoelectric material. In order to achieve higher operating frequencies, the layer thickness must be reduced. As a result, tolerances are becoming increasingly important.

As the layer thickness of the piezoelectric material decreases, the capacitance of the BAW component increases. In order to maintain the wave impedance, the component area must therefore be reduced at the same time. However, acoustic energy is lost at the edge of the component. If the size of the component is reduced, the edge losses increase quadratically with the operating frequency. Therefore, the technology of conventional BAW components (BAW) reaches its limits at approximately 10 GHz.

A BAW component is described in U.S. Patent Application Publication Nos. US 2018/085787 A1 and US 2013/193808 A1, in which the capacitance can be kept low by stacking two different piezo materials with opposite polarities, even at higher operating frequencies, so that the edge losses are reduced and higher operating frequencies in the millimeter wave range can be realized.

The production of heterogeneous piezoelectric bilayers is difficult to master. Furthermore, bimorph effects occur due to temperature influences on the various piezo materials, which can result in thermal drift. Finally, the piezo materials have different piezo properties, which makes the design of low-loss components considerably more difficult.

### SUMMARY

The present invention provides a volume acoustic device and a method for producing a volume acoustic device.

Preferred embodiments of the present invention are disclosed herein.

According to a first aspect, the present invention relates to a volume acoustic device. According to an example embodiment of the present invention, the volume acoustic device includes a first electrode and a second electrode, and a piezoelectric element arranged between the first electrode and the second electrode, wherein the piezoelectric element is designed such that a first electromagnetic signal supplied to the first electrode is converted into an acoustic signal in the piezoelectric element, wherein the acoustic signal is converted back into a second electromagnetic signal in the second electrode. The piezoelectric element comprises at least two piezoelectric layers, preferably of the same material with a rectified polarity, and at least one intermediate layer located between the at least two piezoelectric layers. Acoustic layer thicknesses of the piezoelectric layers and the intermediate layer each correspond to an odd-numbered multiple (1×, 3×, . . . ) of half of the acoustic wavelength of an acoustic signal to be transmitted.

According to a second aspect, the present invention relates to a method for producing a volume acoustic device. According to an example embodiment of the present invention, in the method, a substrate is provided. Furthermore, a first electrode, a second electrode and a piezoelectric element arranged between the first electrode and the second electrode are arranged on the substrate, wherein the piezoelectric element is designed such that a first electromagnetic signal supplied to the first electrode is converted into an acoustic signal in the piezoelectric element, wherein the acoustic signal is converted back into a second electromagnetic signal in the second electrode. The piezoelectric element comprises at least two piezoelectric layers with a rectified polarity and at least one intermediate layer located between the at least two piezoelectric layers. Acoustic layer thicknesses of the piezoelectric layers and the intermediate layer each correspond to an odd-numbered multiple (1×, 3×, . . . ) of half of the acoustic wavelength of an acoustic signal to be transmitted.

The volume acoustic device according to the present invention makes it possible to tap into higher frequency ranges with improved behavior with regard to thermal drift. An (incoming) high-frequency signal can be supplied to the first electrode of the volumetric electrical device. The high-frequency signal is a first electromagnetic wave, which is converted into an acoustic wave by the piezoelectric element at the first electrode and back into a second electromagnetic wave at the opposite second electrode. Given a specific electromagnetic or acoustic frequency, the acoustic wavelength λₐ is determined using the sound velocity cₛ of the relevant layer material according to the following formula:

$${λ}_{a} = {c}_{s} / f .$$

Insofar as the acoustic layer thicknesses dₚ of the piezoelectric layers and the intermediate layer stack correspond to a multiple (1×, 3×, . . . ) of half of the acoustic wavelength of the converted electromagnetic wave (i.e., the acoustic signal), i.e:

$${d}_{p} = ( n + 1 / 2 ) * {λ}_{a}$$

for n={0, 1, . . . }, the incoming signal is transmitted and otherwise reflected. Thus, the volume acoustic device can serve as a volume acoustic resonator.

According to one example embodiment of the present invention, a plurality of such resonators can be suitably interconnected in circuits to form so-called conductor and/or grid configurations. As a result, it is possible to realize filter components that are permeable for defined frequency ranges and can be designed for each frequency band in mobile communications, for example. By means of these filters, signal interference between transmitting and receiving channels both in the communication modules of the mobile terminals and in the base stations can be prevented.

Higher frequencies require lower layer thicknesses, which leads to higher requirements with regard to layer thickness accuracy, for example. Conventionally, the lateral dimensions of the resonators would have to be scaled down simultaneously with decreasing layer thickness, in order to compensate for the increase in capacitance caused by the reduction in layer thickness and to be able to maintain the target impedance value of, for example, 50Ω. However, the reduction in size would result in higher acoustic energy losses, because the ratio of the periphery to the area of the resonators thus increases.

According to the present invention, the capacitance is therefore reduced by inserting at least one additional intermediate layer and a further piezoelectric layer. The insertion of the additional piezoelectric layer and the additional at least one intermediate layer corresponds to a series connection of additional series capacitances, which may now individually assume larger values in each case, since the reciprocal values of the individual capacitances add up to the reciprocal total capacitance in series connections. In this way, the resonators can be dimensioned so as to be laterally larger than would be the case without intermediate layers. As a result, there are lower edge losses and the resonators can be designed and used for higher frequencies.

In order not to destroy the resonance, the total acoustic layer thickness of the intermediate layer is adapted to the acoustic target wavelength in the intermediate layer. Thus, the total acoustic layer thickness of the piezoelectric element corresponds to an odd-numbered multiple (1×, 3×, . . . ) of half of the acoustic wavelength. In particular, this also includes half of the acoustic wavelength itself (i.e. 1×).

The at least one further piezoelectric layer located on the second electrode serves to efficiently convert the acoustic wave back into an electromagnetic wave at the second electrode.

According to a further example embodiment of the present invention, the volume acoustic device comprises a plurality of piezoelectric layers, wherein an intermediate layer is located between two successive piezoelectric layers in each case.

According to a further example embodiment of the volume acoustic device of the present invention, the intermediate layer is formed by a single layer. The acoustic layer thickness of the individual layer corresponds to an odd-numbered multiple (1×, 3×, . . . ) of half of the acoustic wavelength of the acoustic signal to be transmitted, i.e. the target wavelength.

According to a further example embodiment of the volume acoustic device of the present invention, the at least one intermediate layer consists of a plurality of sublayers, wherein the sum of acoustic layer thicknesses of the sublayers corresponds to an odd-numbered multiple (1×, 3×, . . . ) of half of the acoustic wavelength of the acoustic signal to be transmitted. For example, the intermediate layer comprises two sublayers with wavelengths:

$${λ}_{a} / 4 + {λ}_{a} / 4 = {λ}_{a} / 2$$

$$or :$$

$${λ}_{a} / 4 + 5 {λ}_{a} / 4 = 3 {λ}_{a} / 2$$

$$or :$$

$$3 {λ}_{a} / 4 + 3 {λ}_{a} / 4 = 3 {λ}_{a} / 2.$$

Here, in each case the first summand indicates the acoustic layer thickness of the first sublayer and the second summand indicates the acoustic layer thickness of the second sublayer. However, the principle can be applied analogously to more than two sublayers.

According to a further example embodiment of the volume acoustic device of the present invention, the acoustic layer thicknesses of the piezoelectric layers and the intermediate layer each correspond to half of the acoustic wavelength of the acoustic signal to be transmitted. In other words, according to the present invention, the total acoustic layer thickness of the piezoelectric element is then 3 λₐ/2. As a result, a fundamental resonance (i.e., n=0, lowest order) occurs in the intermediate layer and in the piezoelectric layers. This is advantageous because the highest quality factors occur in this case, the filter edges can be particularly steep and the insertion losses can be particularly small.

According to a further example embodiment of the volume acoustic device of the present invention, a material of the intermediate layer comprises dielectrics, such as silicon oxide, silicon nitride, silicon carbide, aluminum oxide or DLC (diamond-like carbon). Preferred materials have intrinsically low dielectric and/or acoustic attenuation and an adapted coefficient of thermal expansion.

According to a further example embodiment of the volume acoustic device of the present invention, the at least one intermediate layer has a multilayer structure, for example consisting of acoustic Bragg reflector layers with odd-numbered multiples (1×, 3×, . . . ) of λₐ/4 layer thicknesses. Suitable material pairs for reflector layers are characterized by differences in the sound velocity of the materials and low material attenuation. Possible materials are, e.g., Ti, Ta or Cu for low sound velocities, or Al, Ni, W or Mo for high sound velocities.

According to a further example embodiment of the volume acoustic device of the present invention, combinations of dielectric and semiconducting and/or metal layers are provided as an intermediate layer or as intermediate layers.

According to a further example embodiment of the volume acoustic device of the present invention, the various intermediate layers described above can occur in any combination. For example, the piezoelectric element can have more than two piezoelectric layers and more than one intermediate layer. In this case, at least one of the intermediate layers can be formed from a single layer with an odd-numbered λₐ/2 layer thickness, and at least one further intermediate layer can be formed from multilayer acoustic Bragg reflector layers with odd-numbered multiples (1×, 3×, . . . ) of λₐ/4 layer thicknesses.

According to a further example embodiment of the volume acoustic device of the present invention, the intermediate layers described above may not only be arranged between the piezoelectric layers, but may also be arranged between one and/or both outer piezoelectric layers and the electrodes or the multilayer acoustic Bragg reflector layers.

According to a further example embodiment of the volume acoustic device of the present invention, a material of the piezoelectric layer comprises AlN or ScAlN. This is advantageous due to the high sound velocity, which allows a comparatively large layer thickness. Other possible materials are, for example, ZnO₂, LiNbO₃ or LiTaO₃.

According to a further example embodiment of the volume acoustic device of the present invention, the first electrode and/or the second electrode are designed as an acoustic Bragg reflector—as described above for the intermediate layer. In this case, a Bragg reflector layer can be inserted between the substrate and the piezoelectric element, as a result of which a loss of acoustic energy into the substrate can be prevented, in order to minimize insertion loss. This is an SMR (solidly mounted resonator) architecture. Due to the good thermal coupling to the substrate, the SMR architecture can advantageously be used in applications in which high power has to be processed, e.g. in base stations and in the transmission path of a mobile radio device.

According to a further example embodiment of the volume acoustic device of the present invention, the first and/or second electrode (and thus the piezoelectric element) is exposed. This is an FBAR (film bulk acoustic resonator) architecture. In this case, the acoustic wave is reflected at the electrode-air surface, which is why the FBAR architecture has low insertion losses, which is favorable for larger bandwidths and for the reception path in the mobile radio device.

According to a further example embodiment of the present invention, the volume acoustic device can be used as a high-precision timing oscillator, in filter components for frequencies in the GHz range (in particular also >10 GHz) or as a gravimetric resonance sensor. The volume acoustic device can be used in particular for high-frequency systems, for example in the mobile radio range (20 Ghz-100 GHz) or radar range.

Further advantages, features and details of the present invention will become apparent from the following description, in which various exemplary embodiments are described in detail with reference to the figures.

### BRIEF DESCRIPTION OF THE DRAWINGS

FIG. 1 is a schematic cross-sectional view of a volume acoustic device according to one example embodiment of the present invention.

FIG. 2 is a schematic cross-sectional view of a volume acoustic device according to a further example embodiment of the present invention.

FIG. 3 is a schematic cross-sectional view of a volume acoustic device according to a further example embodiment of the present invention.

FIG. 4 is a schematic cross-sectional view of a volume acoustic device according to a further example embodiment of the present invention.

FIG. 5 is a flow chart of a method for producing a volume acoustic device according to one example embodiment of the present invention.

### DETAILED DESCRIPTION OF EXAMPLE EMBODIMENTS

In all figures, identical or functionally identical elements and devices are provided with the same reference signs. The numbering of method steps serves the purpose of clarity and is generally not intended to imply a specific chronological order. In particular, a plurality of method steps may also be carried out simultaneously.

The figures shown are to be understood as exemplary embodiments of the present invention. It should be explicitly pointed out that the combination of different features of the individual exemplary embodiments is also well within the scope of the present invention.

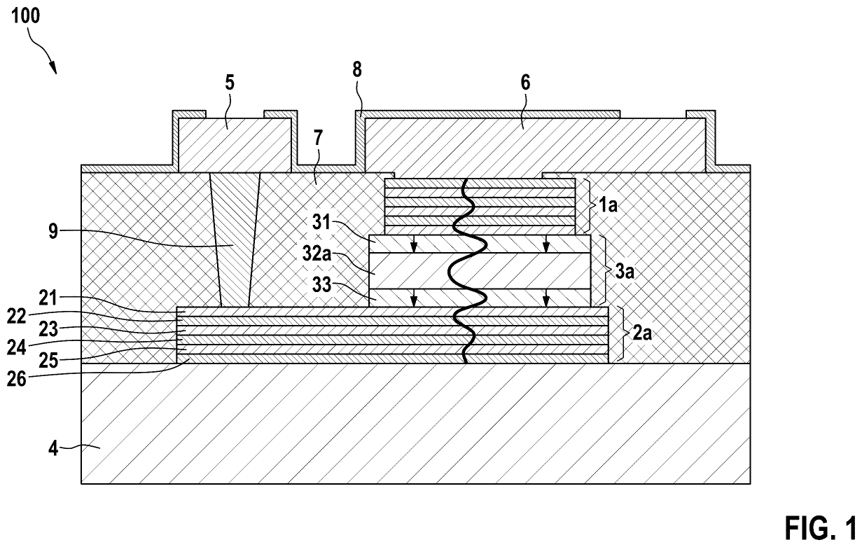

FIG. 1 is a cross-sectional view of a volume acoustic device 100. The volume acoustic device 100 comprises a substrate 4, on which a second acoustic Bragg reflector 2a is arranged. This Bragg reflector comprises a plurality of sublayers 21 to 26 with alternating high and low sound velocity or acoustic impedance. Furthermore, a first acoustic Bragg reflector 1a is provided, which can have a similar structure.

The first Bragg reflector 1a consists of an electrically conductive material and serves as the first electrode and the second Bragg reflector 2a also consists of an electrically conductive material and serves as the second electrode.

A piezoelectric element 3a is arranged between the second Bragg reflector 2a and the first Bragg reflector 1a. A first electromagnetic signal supplied to the first Bragg reflector 1a or the first electrode via a first feed line 6 is converted into an acoustic signal in the piezoelectric element 3 during operation. The acoustic signal is in turn converted back into a second electromagnetic signal in the second Bragg reflector 2a or the second electrode, which is output via a through-connection 9 and a second feed line 5, provided that an acoustic resonance condition is met.

The piezoelectric element 3a comprises two substantially identical piezoelectric layers 31, 33 with a rectified polarity and an intermediate layer 32a located between the two piezoelectric layers 31, 33. Acoustic layer thicknesses of the piezoelectric layers 31, 33 and the intermediate layer 32a in each case correspond to an odd-numbered multiple (1×, 3×, . . . ) of half of the acoustic wavelength of an acoustic signal to be transmitted, i.e. a predetermined acoustic wavelength (corresponding to a predetermined passband frequency of the volume acoustic device). Preferably, as the fundamental first resonance of the piezoelectric element 3a, half of the acoustic wavelength of the desired passband frequency in each case fits into the piezoelectric layers 31, 33 and into the intermediate layer 32a (see the indicated wave).

The first Bragg reflector 1a, the second Bragg reflector 2a, the piezoelectric element 3a and the through-connection 9 are surrounded by a dielectric 7. There is a passivation layer 8 on the feed lines 5, 6 and the dielectric 7 to protect against environmental influences.

For example, a resonator can be designed for a resonance frequency of 24 GHz in the millimeter wave frequency range as shown in Table 1.

TABLE 1

| Reference | | Sound | | Acoustic layer | |
|---|---|---|---|---|---|
| signs | Layer | velocity cₛ | | thickness | |
| 31, 33 | Piezoelectric AlN | 11400 | m/s | 238 nm | (λₐ/2) |
| 32a | Intermediate | 13006 | m/s | 271 nm | (λₐ/2) |
| | layer SiC | | | | |
| 21, 23, 25 | Bragg reflector | 4140 | m/s | 43 nm | (λₐ/4) |
| | layer Ti | | | | |
| 22, 24, 26 | Bragg reflector | 5174 | m/s | 54 nm | (λ_{a/4}) |
| | layer W | | | | |

It should be explicitly pointed out here that an additional intermediate layer 32a can be arranged, for example, between the outer piezoelectric layer 31 and the first Bragg reflector 1a and/or the outer piezoelectric layer 33 and the second Bragg reflector 2a, and that this is certainly to be seen within the scope of the present invention.

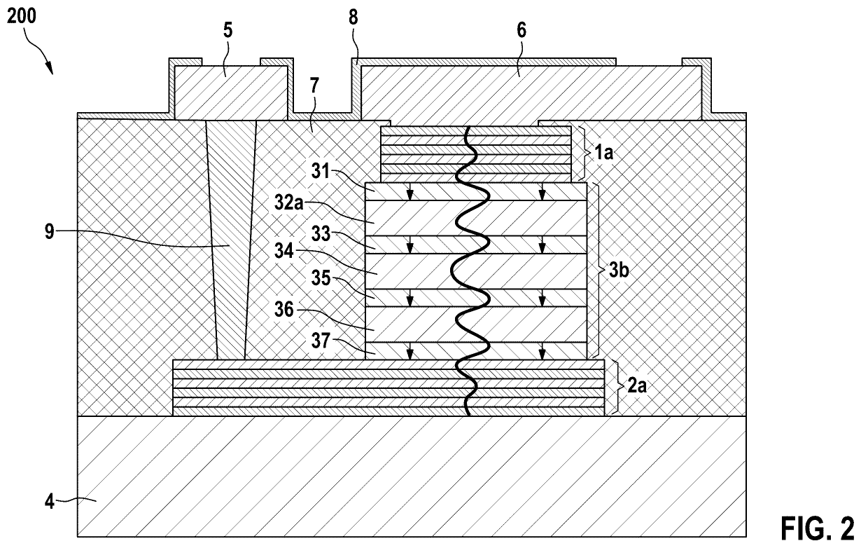

FIG. 2 is a cross-sectional view of a further volume acoustic device 200. In contrast to the volume acoustic device 100 shown in FIG. 1, the piezoelectric element 3b comprises four parallel polarized piezoelectric layers 31, 33, 35, 37, wherein an intermediate layer 32a, 34, 36 is located between two successive piezoelectric layers 31, 33, 35, 37 in each case.

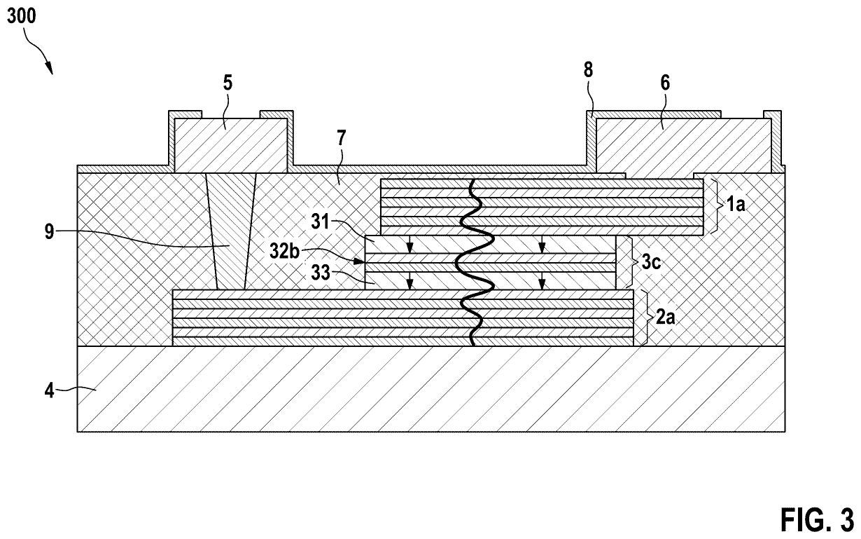

FIG. 3 is a cross-sectional view of a further volume acoustic device 300. In contrast to the volume acoustic device 100 shown in FIG. 1, the piezoelectric element 3c comprises an intermediate layer 32b which consists of two λₐ/4-Bragg reflector layers, wherein λₐ denotes the target wavelength which is to be transmitted, i.e. which corresponds to a desired passband frequency. The thicknesses of the piezo layers 31, 33 and the intermediate layer 32b are selected such that half of the acoustic wavelength of the desired passband frequency in each case fits in as the fundamental first resonance of the total stack. Analogous to that shown in FIG. 2, the device can also have more than two piezoelectric layers 31, 33 and/or more than one intermediate layer 32b.

It should be explicitly pointed out here that the in this case two λₐ/4-Bragg reflector layers can have a different material pairing than the bounding outer Bragg reflector layers of the Bragg reflectors 1a and 2a.

Furthermore, it should be noted that mixed forms of FIGS. 2 and 3, i.e. combinations of intermediate layers 32a and 32b in a device, are also within the scope of the present invention.

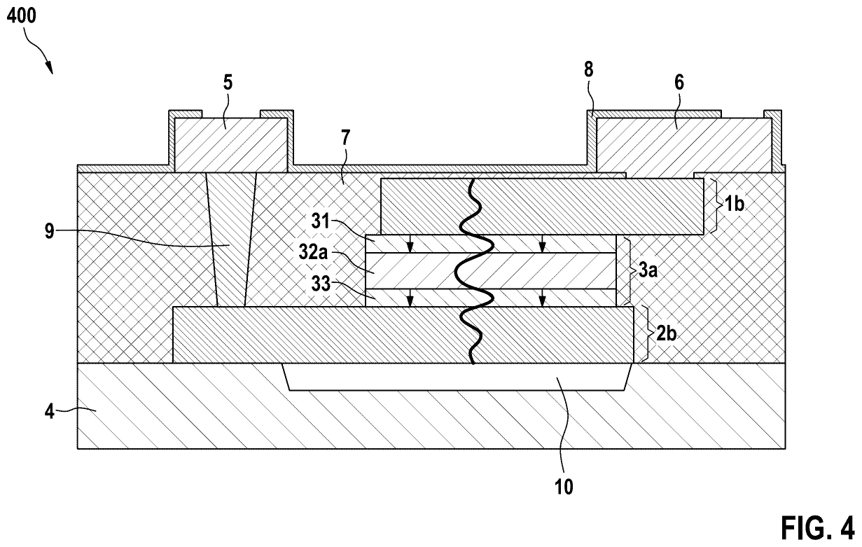

FIG. 4 is a cross-sectional view of a further volume acoustic device 400. In contrast to the volume acoustic device 100 shown in FIG. 1, metal electrodes 1b, 2b, which are not designed as Bragg reflectors, are provided here. The second electrode 2b is exposed, thus forming a cavity 10. The thickness of the electrodes 1b, 2b matches the wavelength of the passband frequency. In this case, the confinement of the acoustic wave is effected by reflection at the surfaces of the electrodes (or passivation) to the ambient air.

Here too, it should be explicitly pointed out that various mixed forms with regard to the shaping of electrodes (metal electrodes 1b/2b or Bragg reflectors 1a/2a) can be combined in one device and are within the scope of the present invention.

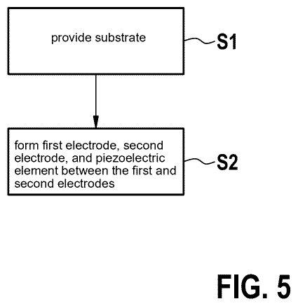

FIG. 5 is a flow chart of a method for producing a volume acoustic device. In particular, one of the volume acoustic devices 100 to 400 shown in FIGS. 1 to 4 can be produced.

In a first method step S1, a substrate 4, for example made of silicon, is provided.

In a second method step S2, a first electrode 1a, 1b, a second electrode 2a, 2b, and a piezoelectric element 3a; 3b; 3c arranged between the first electrode 1a; 1b and the second electrode 2a; 2b are formed on the substrate 4. For this purpose, the second electrode 2a can first be formed on the substrate 4. Subsequently, the piezoelectric element 3a; 3b; 3c is formed on the second electrode 2a, 2b. Finally, the first electrode 1a, 1b is formed on the piezoelectric element 3a; 3b; 3c. Furthermore, a dielectric 7 and feed lines 5, 6 and a passivation layer 8 can be formed.

The piezoelectric element 3a, 3b, 3c is designed such that a first electromagnetic signal supplied to the first electrode 1a, 1b is converted into an acoustic signal in the piezoelectric element 3a, 3b, 3c, wherein the acoustic signal is converted back into a second electromagnetic signal in the second electrode 2a, 2b. The piezoelectric element 3a, 3b, 3c comprises at least two piezoelectric layers 31, 33 (35, 37) with a rectified polarity and at least one intermediate layer 32a (34, 36, 32b) located between the at least two piezoelectric layers 31, 33, 35, 37. Acoustic layer thicknesses of the piezoelectric layers 31, 33, 35, 37 and the intermediate layer 32a, 34, 36; 32b each correspond to an odd-numbered multiple (1×, 3×, . . . ) of half of the acoustic wavelength of an acoustic signal to be transmitted.

1-10. (canceled)

11. A volume acoustic device, comprising:
a first electrode and a second electrode; and
a piezoelectric element arranged between the first electrode and the second electrode, wherein the piezoelectric element is configured such that a first electromagnetic signal supplied to the first electrode is converted into an acoustic signal in the piezoelectric element, wherein the acoustic signal is converted back into a second electromagnetic signal in the second electrode;
wherein the piezoelectric element includes at least two piezoelectric layers with a rectified polarity and at least one intermediate layer located between the at least two piezoelectric layers; and
wherein acoustic layer thicknesses of the piezoelectric layers and the intermediate layer each correspond to an odd-numbered multiple of half of an acoustic wavelength of an acoustic signal to be transmitted.

12. The volume acoustic device according to claim 11, wherein the at least two piezoelectric layers includes a plurality of piezoelectric layers, wherein a respective intermediate layer is located between each two successive piezoelectric layers.

13. The volume acoustic device according to claim 11, wherein the at least one intermediate layer includes a plurality of sublayers, and wherein a sum of acoustic layer thicknesses of the sublayers corresponds to an odd-numbered multiple of half of the acoustic wavelength of the acoustic signal to be transmitted.

14. The volume acoustic device according to claim 11, wherein the acoustic layer thicknesses of the piezoelectric layers and the intermediate layer each correspond to half of the acoustic wavelength of the acoustic signal to be transmitted.

15. The volume acoustic device according to claim 11, wherein the first electrode and/or the second electrode is an acoustic Bragg reflector.

16. The volume acoustic device according to claim 11, wherein the first electrode and/or second electrode are exposed.

17. A method for producing a volume acoustic device, comprising the following steps:
providing a substrate; and
forming a first electrode, a second electrode, and a piezoelectric element arranged between the first electrode and the second electrode on the substrate, wherein the piezoelectric element is configured such that a first electromagnetic signal supplied to the first electrode is converted into an acoustic signal in the piezoelectric element, and wherein the acoustic signal is converted back into a second electromagnetic signal in the second electrode;
wherein the piezoelectric element includes at least two piezoelectric layers with a rectified polarity and at least one intermediate layer located between the at least two piezoelectric layers; and
wherein acoustic layer thicknesses of the piezoelectric layers and the intermediate layer each correspond to an odd-numbered multiple of half of an acoustic wavelength of an acoustic signal to be transmitted.

18. The method according to claim 17, wherein the at least two piezoelectric layers includes a plurality of piezoelectric layers, wherein a respective intermediate layer is located between each two successive piezoelectric layers.

19. The method according to claim 17, wherein the at least one intermediate layer is formed from a plurality of sublayers, wherein a sum of acoustic layer thicknesses of the sublayers corresponds to an odd-numbered multiple of half of the acoustic wavelength of the acoustic signal to be transmitted.

20. The method according to claim 17, wherein the first electrode and/or second electrode is exposed.
